(19) United States
(12) Patent Application Publication
(10) Pub. No.: US 2005/0237097 A1
(43) Pub. Date: Oct. 27, 2005

(54) Low-power high-speed latch and data storage device having the latch

(76) Inventor: Min-Su Kim, Hwaseong-gun (KR)

Correspondence Address: HARNESS, DICKEY & PIERCE, P.L.C., P.O. BOX 8910, RESTON, VA, 20195, US

(21) Appl. No.: 11/099,592

(22) Filed: Apr. 6, 2005

(30) Foreign Application Priority Data
Apr. 26, 2004 (KR) 2004-28633

(51) Int. Cl. H03K 3/037

(52) U.S. Cl. 327/218

(57) ABSTRACT

A latch and a data storage device including the latch are provided. The data storage device includes a pulse generator to produce a first control signal and a second control signal. The latch include: a first inverter to invert an input signal; a non-CMOS switch to selectively pass the inverted input signal output by the first inverter to a node; a second inverter to provide a first inverted version of a middle signal on the node; a first power supply to controllably raise a voltage of the middle signal according to the first inverted version of the middle signal; a second power supply to controllably lower a voltage of the middle signal according to the first inverted version of the middle signal and the second control signal, and a third inverter to provide, as an output signal, a second inverted version of the middle signal on the node.

### CROSS-REFERENCE TO RELATED APPLICATION

This application claims the priority of Korean Patent Application No. 2004-28633, filed on Apr. 26, 2004, in the Korean Intellectual Property Office, the disclosure of which is incorporated herein in its entirety by reference.

### BACKGROUND OF THE PRESENT INVENTION

FIG. 1 is a circuit diagram of a latch circuit according to the Background Art. Referring to FIG. 1, the latch circuit includes a plurality of MOS transistors, a plurality of inverters, and a transmission gate TG.

The transmission gate TG has a PMOS transistor and an NMOS transistor and transmits an input signal D to a corresponding inverter according to a clock signal C and a complementary clock signal Cb.

Generally, electron mobility of an NMOS transistor is greater by at least two times than hole mobility of a PMOS transistor. Accordingly, an operation speed of a PMOS transistor is slower than an operation speed of an NMOS transistor.

Therefore, in order to satisfy a desired operation speed of the transmission gate TG, it is necessary to increase the size of the PMOS transistor. However, as the size of the PMOS transistor increases, the consumption power of the PMOS transistor increases, which also increases a consumption power of the latch circuit that includes the transmission gate TG.

### SUMMARY OF THE PRESENT INVENTION

At least one embodiment of the present invention provides a low-power high-speed latch and at least one other embodiment of the present invention provides a data storage device including the same.

According to at least one embodiment of the present invention, such a latch may include: a first inverter to invert an input signal; a non-CMOS switch to selectively pass the inverted input signal output by the first inverter to a node; a second inverter to provide a first inverted version of a middle signal on the node; a first power supply to controllably raise a voltage of the middle signal according to the first inverted version of the middle signal; a second power supply to controllably lower a voltage of the middle signal according to the first inverted version of the middle signal and the second control signal, and a third inverter to provide, as an output signal, a second inverted version of the middle signal on the node.

According to at least one embodiment of the present invention, such a latch may be a dual latch circuit that includes: a first inverter to invert a first input signal; a second inverter to invert a second input signal; a switching circuit to selectively pass the inverted first and second input signals output by the first and second inverters to a first node and a second node, respectively; a first power supply to controllably adjust a voltage of the second middle signal according to the first middle signal; a second power supply to controllably adjust a voltage of the first middle signal according to the second middle signal; a third inverter to provide an inverted version of a first middle signal on the first node as a first output signal; and a fourth inverter to provide an inverted version of a second middle signal on the second node as a second output signal.

Additional features and advantages of the present invention will be more fully apparent from the following detailed description of example embodiments, the accompanying drawings and the associated claims.

### BRIEF DESCRIPTION OF THE DRAWINGS

The above and other features and advantages of the present invention will become more apparent by describing in detail example embodiments thereof with reference to the attached drawings in which:

FIG. 1 is a circuit diagram of a latch circuit according to the Background Art;

FIG. 2 is a block diagram of a data flip-flop, according to at least one embodiment of the present invention;

FIG. 3 is a circuit diagram of a pulse generator of FIG. 2, according to at least one embodiment of the present invention;

FIG. 4 shows in more detail an example of the latch of FIG. 2, according to at least one embodiment of the present invention; and

FIG. 5 shows a latch of FIG. 2, according to at least one other embodiment of the present invention.

Some portions of the drawings may be exaggerated for clarity, hence, the drawings are not to be considered as drawn to scale unless explicitly noted. In the drawings, whenever the same element reappears in subsequent drawings, it is denoted by the same reference numeral.

While example embodiments of the present invention are described more fully with reference to the accompanying drawing, the present invention may be embodied in many different forms and should not be construed as being limited to the example embodiments set forth herein; rather, these example embodiments are provided so that this disclosure is thorough and complete, and conveys the concept of the present invention to those skilled in the art.

### DETAILED DESCRIPTION OF EXAMPLE EMBODIMENTS OF THE PRESENT INVENTION

Hereinafter, the present invention will be described in detail by explaining example embodiments of the present invention with reference to the attached drawings.

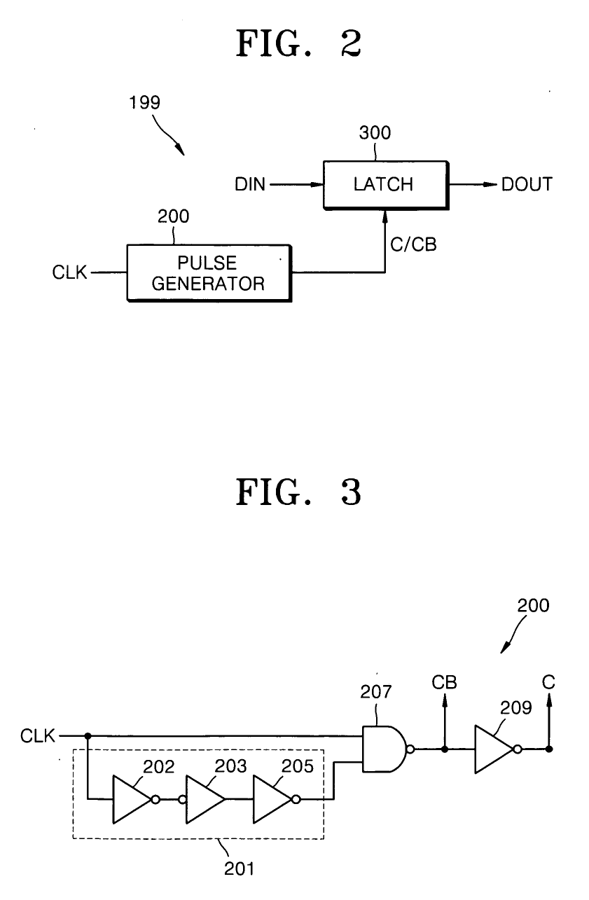

FIG. 2 is a block diagram of a type of circuit known as a data flip-flop 199 (also known as a bi-stable gate) according to at least one embodiment of the present invention. The flip-flop 199 includes a pulse generator 200 and a latch 300. The pulse generator 200 receives a clock signal CLK and generates a first control signal C and a second control signal \overline{C} (hereafter, CB) that can be an inverted version of the first control signal C.

The latch 300 latches at least an input signal DIN at a high speed using low power, according to the first control signal C and the second control signal CB.

FIG. 3 is a circuit diagram of the pulse generator 200 of FIG. 2. The pulse generator 200 includes an inverter chain 201 (that itself includes a plurality of inverters 202, 203, and 205), a NAND gate 207, and an inverter 209. The inverter chain 201 acts as a delay device for delaying the clock signal CLK by an amount of corresponding time to the cumulative propagation delay of the clock signal CLK through the inverters 202, 203 and 205. As the circumstances to which pulse generator 200 is applied will vary, the number of inverters in the inverter chain 201 can correspondingly vary.

The NAND gate 207 performs a NAND operation upon the clock signal CLK and an output signal of the inverter chain 201 (e.g., the output signal of the inverter 205), and outputs the NANDed result (as the second control signal CB) to the latch 200 and to the inverter 209. The inverter 209 inverts the second control signal CB and outputs the inverted result as the first control signal C to the latch 300.

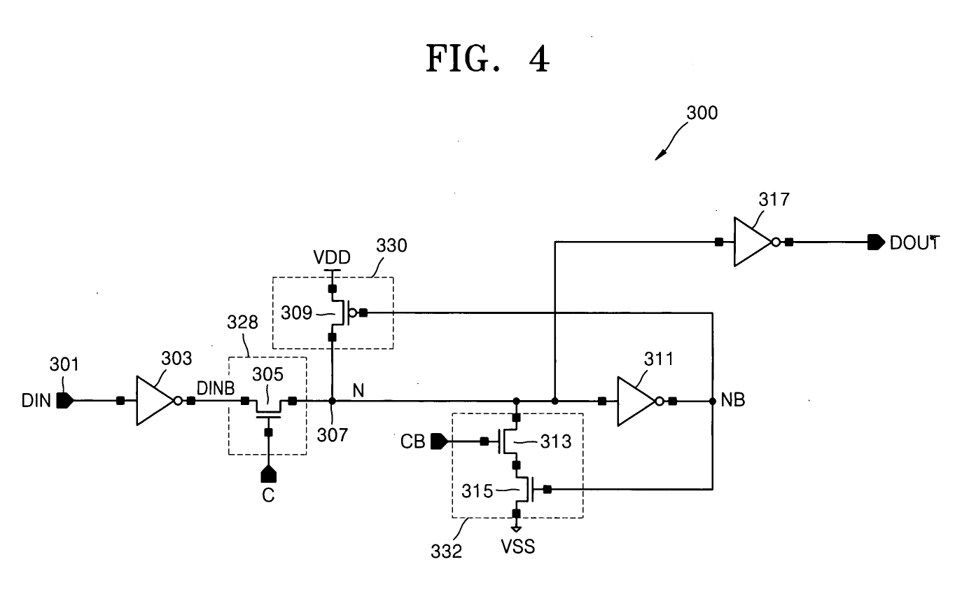

FIG. 4 shows in more detail an example of the latch 300 of FIG. 2, according to at least one embodiment of the present invention. As depicted in FIG. 4, the latch 300 is an example of a single latch. A first inverter 303 receives an input signal DIN through an input terminal 301 and inverts the input signal DIN to form a signal DINB.

A switch 328, e.g., an NMOS transistor 305, selectively passes the signal DNB to a node 307 in response to the first control signal C (that is provided, e.g., to the gate of the NMOS transistor 309). A first power supply circuit 330, e.g., including a PMOS transistor 309, supplies a supply voltage, e.g., VDD, to the node 307 in response to an output signal of a second inverter 311 (that is provided, e.g., to a gate of the PMOS transistor). The first power supply circuit 332 can raise the voltage of a signal N on the node 307 by selectively supplying the supply voltage VDD to the node 307.

A second inverter 311 receives the signal N that is on the node 307, inverts the signal to form a signal NB, and outputs the signal DNB to the gate of the PMOS transistor 309 and a gate of an NMOS transistor 315.

A second power supply circuit 332, e.g., can include two NMOS transistors 313 and 315 that are serially connected between the node 307 and a ground voltage, e.g., VSS. The second control signal CB is input to a gate of the NMOS transistor 313, and the output signal of the second inverter 311 is input to a gate of the NMOS transistor 315. Accordingly, the second power supply circuit 332 supplies the ground voltage VSS to the node 307 according to the second control signal CB and the output signal of the second inverter 311.

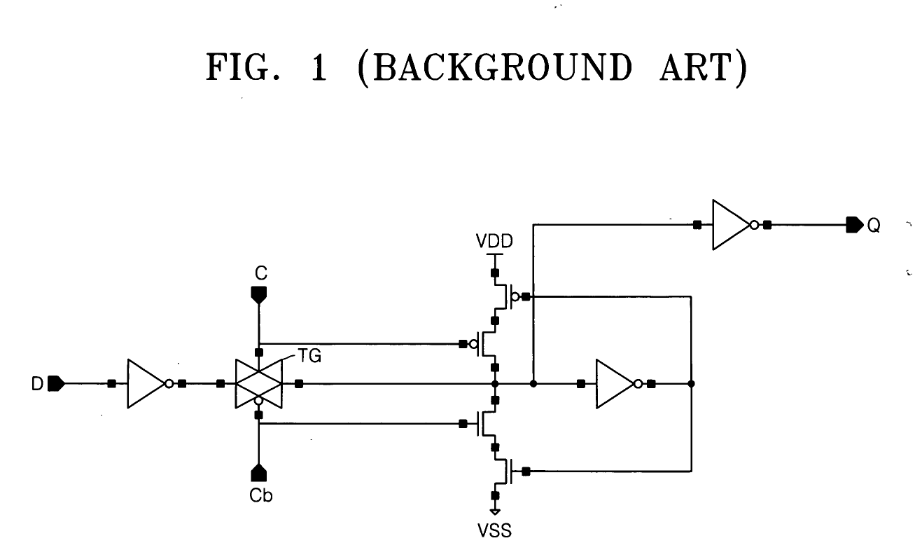

A third inverter 317 receives and inverts the signal N on the node 307, and provides the inverted signal as an output signal DOUT. The latch 300 of FIG. 4 (more specifically the switch 238), as contrasted with the transmission gate TG shown in Background Art FIG. 1, does not include the PMOS transistor of the transmission gate TG. Therefore, by contrast to Background Art FIG. 1, the latch circuit 300 can occupy a smaller area, the switch 305 can have a faster operation speed, and the consumption of power by the transmission circuit 305 and the latch 300 together in FIG. 4 can be lower.

If the first control signal C is in a logic high state and the second control signal CB is in a logic low state, then the latch 300 can also latch, in the form of the signal N at the node 107, a state (for example, logic high or logic low) of the signal DINB. The latch 300 can be described as latching a state of the input signal DIN in the form of the signal DOUT, according to the following equation.

$$DOUT = \overline{MID} = \overline{DINB} = DIN \qquad 1 )$$

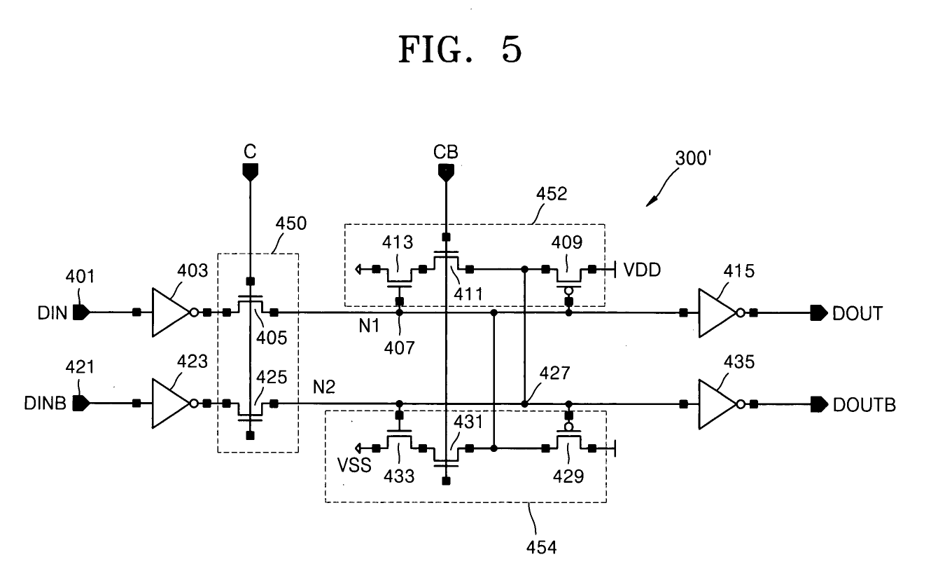

FIG. 5 shows in more detail another example (namely 300′) of a latch 300 of FIG. 2, according to another embodiment of the present invention. As depicted in FIG. 5, the latch 300′ is a double latch.

An inverter 403 receives a first input signal DIN through a first input terminal 401 and inverts the first input signal DIN. An inverter 423 receives a second input signal DINB through a second input terminal 421 and inverts the second input signal DINB. The second input signal DINB may be an inverted version of the first input signal DIN.

A switching circuit 450 can include two NMOS transistors 405 and 425. The switching circuit 450 transmits signals output from a pair of first inverters 403 and 423 to corresponding first and second nodes 407 and 427, respectively, in response to a first control signal C.

A second inverter 415 inverts a signal N1 on the first node 407 and outputs the inverted signal as a first output signal DOUT. A third inverter 435 inverts a signal N2 on the second node 427 and outputs the inverted signal as a second output signal DOUTB. The first output signal DOUT and the second output signal DOUTB may be complimentary signals. In other words, the second output signal DOUTB may represent an inverted version of the first output signal DOUT.

A first power supply circuit 452 can include transistors 409 (PMOS), 411 (NMOS), and 413 (NMOS) that are serially connected between a supply voltage, e.g., VDD and a ground voltage e.g., VSS, wherein gates of the respective transistors 409 and 413 are connected to the first node 407 and the second control signal CB is input to a gate of the transistor 411.

The first power supply circuit 452 selectively supplies the supply voltage VDD or the ground voltage, VSS to the second node 427, according to a voltage level of the second control signal CB and a voltage level of the signal N2 on the first node 407.

A second power supply circuit 454 can include transistors 429 (PMOS), 431 (NMOS), and 433 (NMOS) that are serially connected between the supply voltage VDD and the ground voltage VSS, wherein gates of the respective transistors 419 and 433 are connected to the second node 427 and the second control signal CB is input to a gate of the transistor 431.

The second power supply circuit 454 selectively supplies the supply voltage VDD or the ground voltage to the first node 407, according to a voltage level of the second control signal CB and a voltage level of the signal N2 on the second node 427.

If the first control signal C is in a logic high state and the second control signal CB is in a logic low state, the latch 300′ latches a state of the first input signal DIN and a state of the second input signal DINB, respectively.

As described above, example embodiments of latches and data storage devices including such latches, according to the present invention, can operate at a high-speed with low power.

While the present invention has been particularly shown and described with reference to example embodiments thereof, it will be understood by those of ordinary skill in the art that various changes in form and details may be made therein without departing from the spirit and scope of the present invention.

1. A latch comprising:
a first inverter inverting an input signal;
a non-CMOS switch to selectively pass an output signal of the first inverter to a node in response to a first control signal;
a second inverter inverting a signal of the node;
a third inverter inverting the signal of the node and outputting the inverted result as an output signal;
a first power supply circuit supplying a supply voltage to the node according to an output signal of the second inverter; and
a second power supply circuit supplying a ground voltage to the node according to a second control signal and the output signal of the second inverter.

2. The latch of claim 1, wherein the non-CMOS switch is an NMOS transistor which transmits the output signal of the first inverter to the node according to a state of a first control signal received through a gate of the NMOS transistor.

3. The latch of claim 1, wherein the first power supply circuit includes a PMOS transistor that is controllable to pass the supply voltage to the node, a gate of the PMOS transistor being provided with an output signal of the second inverter.

4. The latch of claim 1, wherein the second power supply circuit includes first and second NMOS transistors connected in serial between the node and the ground voltage;
the second control signal is provided to a gate of the first NMOS transistor; and
the output signal of the second inverter is provided to a gate of the second NMOS transistor.

5. A latch comprising:
a pair of first inverters inverting a pair of input signals, respectively;
a switching circuit passing output signals from the pair of first inverters to corresponding first and second nodes, respectively, in response to a first control signal;
a second inverter inverting a signal of the first node and outputting the inverted result as a first output signal;
a third inverter inverting a signal of the second node and outputting the inverted result as a second output signal;
a first power supply circuit supplying one of a supply voltage and a ground voltage to the second node, according to a second control signal and the signal of the first node; and
a second power supply circuit supplying one of the supply voltage and the ground voltage to the first node according to the second control signal and the signal of the second node.

6. The latch of claim 5, wherein the switching circuit comprises:
a first NMOS transistor transmitting an output signal of one of the pair of first inverters to the first node in response to the first control signal; and
a second NMOS transistor transmitting an output signal of the other one of the pair of first inverters to the second node in response to the first control signal.

7. A data storage device comprising:
a pulse generator receiving a clock signal and generating first and second control signals that are complimentary signals; and
a latch latching an input signal according to the first control signal and the second control signal, the latch including the following,
a first inverter inverting the input signal,
a non-CMOS switch to selectively pass an output signal of the first inverter to a node in response to the control signal,
a second inverter inverting a signal of the node,
a third inverter inverting a signal of the node and outputting the inverted result as an output signal,
a first power supply circuit supplying a supply voltage to the node according to an output signal of the second inverter, and
a second power supply circuit supplying a ground voltage to the node according to a second control signal and the output signal of the second inverter.

8. A data storage device comprising:
a pulse generator generating a clock signal and generating first and second control signals that are complimentary signals; and
a latch latching a pair of input signals according to the first control signal and the second control signal, the latch including the following,
a pair of first inverters inverting the pair of input signals, respectively,
a switching circuit selectively passing output signals from the pair of first inverters to corresponding first and second nodes, respectively, in response to the first control signal,
a second inverter inverting a signal of the first node,
a third inverter inverting a signal of the second node,
a first power supply circuit supplying one of a supply voltage and a ground voltage to the second node according to the second control signal and the signal of the first node, and
a second power supply circuit supplying one of the supply voltage and the ground voltage to the first node according to the second control signal and the signal of the second node.

9. A latch circuit comprising:
a first inverter to invert an input signal;
a non-CMOS switch to selectively pass the inverted input signal output by the first inverter to a node;
a second inverter to provide a first inverted version, MB1, of a middle signal on the node;
a first power supply to controllably raise a voltage of the middle signal according to the signal MB1;
a second power supply to controllably lower a voltage of the middle signal according to the signal MB1; and
a third inverter to provide, as an output signal, a second inverted version of the middle signal on the node.

10. The latch circuit of claim 9, wherein:
the non-CMOS switch is an NMOS transistor.

11. The latch circuit of claim 9, wherein:
the non-CMOS switch is controllable according to a first control signal; and
the second power supply is further controllable according to a second control signal.

12. The latch circuit of claim 11, wherein:
the first control signal is an inverted version of the first control signal.

13. A flip-flop comprising:
a pulse generator to produce a first control signal and a second control signal; and
latch circuit including the following,
a first inverter to invert an input signal,
a non-CMOS switch to selectively pass the inverted input signal output by the first inverter to a node;
a second inverter to provide a first inverted version of a middle signal on the node,
a first power supply to controllably raise a voltage of the middle signal according to the first inverted version of the middle signal,
a second power supply to controllably lower a voltage of the middle signal according to the first inverted version of the middle signal and the second control signal, and
a third inverter to provide, as an output signal, a second inverted version of the middle signal on the node.

14. The flip-flop circuit of claim 13, wherein:
the first control signal is an inverted version of the second control signal.

15. A dual latch circuit comprising:
a first inverter to invert a first input signal;
a second inverter to invert a second input signal;
a switching circuit to selectively pass the inverted first and second input signals output by the first and second inverters to a first node and a second node, respectively;
a first power supply to controllably adjust a voltage of the second middle signal according to the first middle signal;
a second power supply to controllably adjust a voltage of the first middle signal according to the second middle signal;
a third inverter to provide an inverted version of a first middle signal on the first node as a first output signal; and
a fourth inverter to provide an inverted version of a second middle signal on the second node as a second output signal.

16. The dual latch circuit of claim 15, wherein:
the switching circuit includes at least two NMOS transistors connected between the first and second inverters and the first and second nodes, respectively.

17. The dual latch circuit of claim 15, wherein:
the switching circuit is controllable according to a first control signal; and
the first and second power supplies are further controllable according to a second control signal.

18. The dual latch circuit of claim 17, wherein:
the first control signal is an inverted version of the second control signal.

19. A dual flip-flop comprising:
a pulse generator to produce a first control signal and a second control signal; and
latch circuit including the following,
a first inverter to invert a first input signal;
a second inverter to invert a second input signal;
a switching circuit to selectively pass the inverted first and second input signals output by the first and second inverters to a first node and a second node, respectively, according to a first control signal;
a first power supply to controllably adjust a voltage of the second middle signal according to the first middle signal and a second control signal;
a second power supply to controllably adjust a voltage of the first middle signal according to the second middle signal and the second control signal;
a third inverter to provide an inverted version of a first middle signal on the first node as a first output signal; and
a fourth inverter to provide an inverted version of a second middle signal on the second node as a second output signal.

20. The dual flip-flop of claim 19, wherein:
the pulse generator is operable to form the first control signal by inverting the second control signal.
